(19) United States
(12) Patent Application Publication
(10) Pub. No.: US 2012/0118377 A1
(43) Pub. Date: May 17, 2012

(54) DYE-SENSITIZED SOLAR CELL

(76) Inventors: Byong-Cheol Shin, Yongin-si (KR); Ji-Won Lee, Yongin-si (KR); Do-Young Park, Yongin-si (KR); Moon-Sung Kang, Yongin-si (KR); Chang-Wook Kim, Yongin-si (KR); Si-Young Cha, Yongin-si (KR); Jae-Hyoung Park, Yongin-si (KR)

(21) Appl. No.: 13/173,505

(22) Filed: Jun. 30, 2011

(30) Foreign Application Priority Data
Nov. 16, 2010 (KR) 10-2010-0114029

(51) Int. Cl. H01L 31/0232

(52) U.S. Cl. 136/259

(57) ABSTRACT

A dye-sensitized solar cell includes a first electrode, a light absorption layer disposed on one side of the first electrode, a second electrode facing the first electrode, a light reflecting layer disposed on one side of the second electrode, and an electrolyte filled between the first electrode and the second electrode. Here, the light reflecting layer includes a plurality of thin films including a first oxide thin film and a second oxide thin film, the first oxide thin film has a different refractive index from the second oxide thin film, and the first and second oxide thin films are stacked alternately.

### CROSS-REFERENCE TO RELATED APPLICATION

This application claims priority to and the benefit of Korean Patent Application No. 10-2010-0114029, filed in the Korean Intellectual Property Office, on Nov. 16, 2010, the entire content of which is incorporated herein by reference.

### BACKGROUND

1. Field

The following disclosure relates to a dye-sensitized solar cell.

2. Description of Related Art

Diverse research has been carried out in an attempt to develop energy sources that can replace conventional fossil fuels and solve the approaching energy crisis. Particularly, extensive research is underway to find ways for using alternative energy sources, such as wind power, atomic power, and solar power, as substitutes for petroleum resources, which are expected to be depleted within several decades. Among the alternative energy sources, solar cells use solar energy that is infinite and environmentally friendly, as opposed to other energy sources. Since 1983 when a selenium (Se) solar cell was first produced, solar cells have been highlighted. Also, silicon (Si) solar cells have recently been drawing a lot of attention from researchers.

However, it is difficult to practically use Si solar cells because the production cost is high and there are difficulties in improving cell efficiency. To overcome the problems, researchers are studying development of a dye-sensitized solar cell that can be produced at a low cost.

The dye-sensitized solar cell includes photosensitive dye molecules that absorb visible rays and produce electron-hole pairs, excitons, and a transition metal oxide that transfers the produced electrons.

However, since the photosensitive dye is positioned in a dye-sensitized solar cell locally, a majority of light entered into the dye-sensitized solar cell may not reach the photosensitive dye. Additionally, because a photosensitive dye absorbs solar light having a specific wavelength region, there are limits for absorbing solar light.

### SUMMARY

An aspect of an embodiment of the present invention is directed toward a dye-sensitized solar cell capable of improving efficiency.

According to one embodiment of the present invention, a dye-sensitized solar cell is provided that includes a first electrode, a light absorption layer disposed on one side of the first electrode, a second electrode facing the first electrode, a light reflecting layer disposed on one side of the second electrode and an electrolyte filled between the first electrode and the second electrode, wherein the light reflecting layer includes a plurality of thin films including a first oxide thin film and a second oxide thin film, the first oxide thin film having a different refractive index from the second oxide thin film, and the first and second oxide thin films being stacked alternately.

The first oxide thin film may include a titanium oxide (TiO₂), and the second oxide thin film may include a silicon oxide (SiO₂).

Each of the first oxide thin film and the second oxide thin film may be formed to have a thickness at 10 nm or 800 nm or between 10 nm and 800 nm.

The second oxide thin film may be formed thicker than the first oxide thin film.

The light reflecting layer may reflect light of wavelength at 380 nm or 750 nm or between 380 nm and 750 nm.

The light reflecting layer may have a light reflecting wavelength varying in accordance to the thicknesses of the first oxide thin film and the second oxide thin film.

The light reflecting layer may have a reflectance higher than about 100%.

The light absorption layer may include a titanium oxide (TiO₂) and a photosensitive dye adsorbed to TiO₂.

The second electrode may include Pt, Au, Ni, Cu, Ag, In, Ru, Pd, Rh, Ir, Os, C, a conductive polymer or a combination thereof.

At least one of the first electrode or the second electrode is supported by a conductive transparent substrate and the conductive transparent substrate may include indium tin oxide, fluorine tin oxide, ZnO—(Ga₂O₃ or Al₂O₃), tin oxide, zinc oxide, or a combination thereof.

In view of the foregoing, the efficiency may be improved by increasing the optical amount absorbed by a dye-sensitized solar cell.

### BRIEF DESCRIPTION OF THE DRAWINGS

FIG. 1 is a cross-sectional view illustrating a dye-sensitized solar cell in accordance with an embodiment of the present invention.

FIG. 2 is a cross-sectional enlarged view enlarging a light reflecting layer of the dye-sensitized solar cell shown in FIG. 1.

FIGS. 3A to 3D are graphs showing the optical reflectances (diffusive reflectances) of dye-sensitized solar cells according to Examples 1 to 4.

FIG. 4 is a graph showing the current density of the dye-sensitized solar cells according to Example 4 and Comparative Example 1.

### DETAILED DESCRIPTION OF THE EMBODIMENTS

Exemplary embodiments will hereinafter be described in detail. However, these embodiments are only exemplary, and the present invention is not limited thereto.

In the drawings, the thickness of layers, regions, etc., are exaggerated for clarity. Like reference numerals designate like elements throughout the specification. It is to be understood that when an element such as a layer, film, region, or substrate is referred to as being “on” another element, it can be directly on the other element or one or more intervening elements may also be present therebetween. In contrast, when an element is referred to as being “directly on” another element, there are no intervening elements present therebetween.

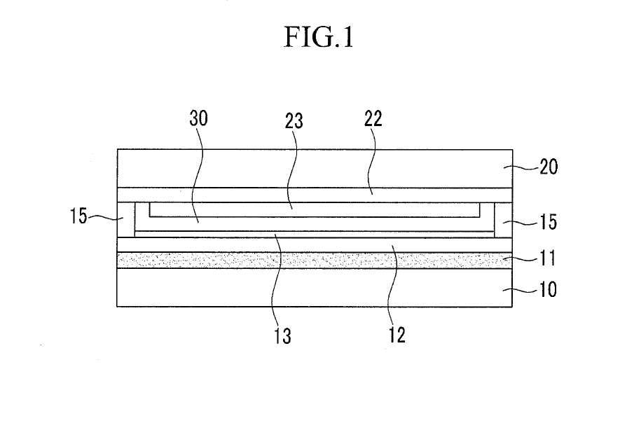

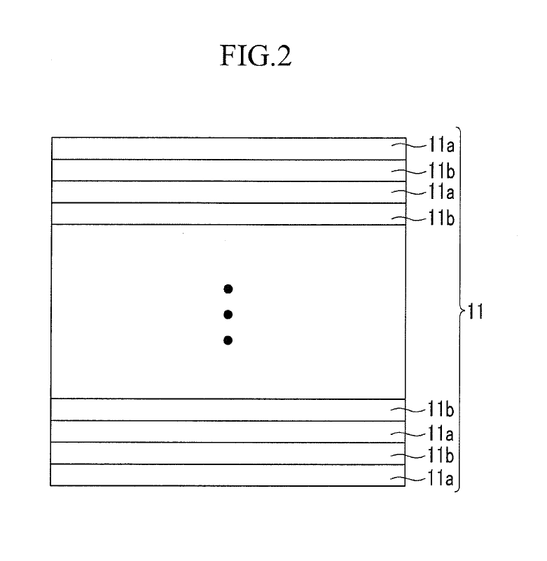

Hereinafter, a dye-sensitized solar cell according to one embodiment is described in detail referring to FIGS. 1 and 2.

FIG. 1 is a cross-sectional view illustrating a dye-sensitized solar cell in accordance with an embodiment of the present invention, and FIG. 2 is a cross-sectional enlarged view enlarging a light reflecting layer of the dye-sensitized solar cell shown in FIG. 1.

Referring to FIG. 1, the dye-sensitized solar cell includes a lower substrate 10 and an upper substrate 20 which face (or oppose) each other and is fixed with a spacer 15; a lower electrode 12 and an upper electrode 22 which are respectively disposed on one side of the lower substrate 10 and the upper substrate 20; a light reflecting layer 11 disposed on one side of the lower electrode 12; an auxiliary electrode 13 disposed on the other side of the lower electrode 12; a light absorption layer 23 disposed on one side of the upper electrode 22; and an electrolyte 30 filling the space between the lower substrate 10 and the upper substrate 20.

The lower substrate 10 and the upper substrate 20 may be formed of transparent glass or polymer, and the polymer may include polyacrylate, polyethyleneetherphthalate, polyethylenenaphthalate, polycarbonate, poly arylate, polyetherimide, polyethersulfone, and/or polyimide.

Each of the lower electrode 12 and the upper electrode 22 may be formed of a transparent conductor, and may include an inorganic conductive material such as indium tin oxide (ITO), fluorine tin oxide (FTO) or antimony-doped tin oxide (ATO), or an organic conductive material such as polyacetylene or polythiophene.

The light reflecting layer 11 is a layer which reflects light of a wavelength region of about 380 nm to about 750 nm (reflects light of wavelength at 380 nm or 750 nm or between 380 nm and 750 nm), and it is described hereafter with reference to FIG. 2.

Referring to FIG. 2, the light reflecting layer 11 includes a plurality of thin films including a first oxide thin film 11a and a second oxide thin film 11b having a different refractive index from each other and stacked alternately. In one embodiment, the thin films include a number (N) first oxide thin films 11a and a number (N) of second oxide thin films 11b, and N may be 1 or more. In one embodiment, N is 2 or more. In one embodiment, N is 9.

For example, the first oxide thin film 11a may include titanium oxide (TiO₂), and the second oxide thin film 11b may include silicon oxide (SiO₂).

When it is assumed that the number (N) of first oxide thin films 11a and the number (N) of second oxide thin films 11b are stacked alternatively (i.e., one of the number (N) of first oxide films 11a on one of the number (N) of second oxide films 11b), a wavelength region capable of reflecting light may be selected based on the thickness of each layer. In other words, a reflecting wavelength region may be selected by controlling the thickness of each layer.

For example, the thickness may be set to λ/4 for a particular wavelength, and the thickness may satisfy the following:

Thickness (t₁)=λ/4n₁ (1)

Thickness (t₂)=λ/4n₂ (2)

where n₁ denotes a refractive index of titanium oxide; n₂ denotes a refractive index of silicon oxide; and λ denotes a particular wavelength region.

Each of the first oxide thin film 11a and the second oxide thin film 11b may be formed in a thickness ranging from about 10 nm to about 800 nm (at 10 nm or 800 nm or between 10 nm and 800 nm), and according to one embodiment, each of the first oxide thin film 11a and the second oxide thin film 11b may be formed in a thickness ranging from about 10 nm to about 200 nm (at 10 nm or 200 nm or between 10 nm and 200 nm). Herein, when it is assumed that the first oxide thin film 11a includes titanium oxide and the second oxide thin film includes silicon oxide, the second oxide thin film 11b may be formed thicker than the first oxide thin film 11a.

The auxiliary electrode 13 is a catalyst electrode activating a redox couple. For example, the auxiliary electrode 13 may include Pt, Au, Ni, Cu, Ag, In, Ru, Pd, Rh, Ir, Os, C, a conductive polymer or a combination thereof.

The light absorption layer 23 may include a photosensitive dye and a porous layer with particles adsorbing the photosensitive dye.

The photosensitive dye may be formed of a metal composite including aluminum (Al), platinum (Pt), palladium (Pd), europium (Eu), lead (Pb), iridium (Ir), and ruthenium (Ru). Herein, since ruthenium is an element belonging to a platinum group and is capable of forming many organic metal composites, a dye including ruthenium is used. For example, Ru(etc bpy)₂(NCS)₂.2CH₃CN-type is used. Here, in the dye example, “etc” is (COOEt)₂ or (COOH)₂; and it is a functional group that may be bonded with the surface of the porous layer (e.g., particles of TiO₂). Also, a dye including an organic pigment may be used, and non-limiting examples of the organic pigment include coumarin, porphyrin, xanthene, riboflavin, and triphenylmethane. The photoelectric conversion efficiency may be improved by using them alone or together with a Ru composite to improve the visible light absorption of long wavelengths.

The porous layer may include particulates having a fine and uniform nano-sized average particle diameter and are distributed uniformly while keeping porosity. The porous layer may have a suitable roughness on its surface. Non-limiting examples of the porous layer may include TiO₂, SnO₂, ZnO, WO₃, Nb₂O₅, TiSrO₃ or a mixture thereof, and among them, anatase-type TiO₂ may be used.

Herein, the particulates may allow the porous layer to have a large surface area so that the photosensitive dye adsorbed on the surface may absorb more light. Accordingly, the particulates constituting the porous layer may have a fine average particle diameter ranging from about 5 nm to about 500 nm (at 5 nm or 500 nm or between 5 nm and 500 nm). Since the particulates have an average particle diameter in the above range and according to one embodiment, the surface area is enlarged and this increases the adsorption amount of the photosensitive dye while securing adhesion strength to a substrate structure during a heat treatment that is performed after the porous layer is formed.

The spacer 15 may provide an electrolyte impregnation space while preventing (or protecting) a light absorption layer 23 from being pressed during a process for manufacturing a dye-sensitized solar cell.

The electrolyte 30 provides a material promoting an oxidation/reduction reaction of a color-changing electric material, and it may be a liquid electrolyte or a solid polymer electrolyte. As for the liquid electrolyte, a solution (in which a lithium salt such as LiOH or LiClO₄, a potassium salt such as KOH, and a sodium salt such as NaOH that are dissolved in a solvent) may be used but this disclosure is not limited thereto. As for the solid electrolyte, poly(2-acrylamino-2-methylpropane sulfonic acid or polyethyleneoxide(poly(ethylene oxide)) may be used, but is not limited thereto.

The dye-sensitized solar cell according to one embodiment of this disclosure may increase the optical amount absorbed by a dye by including a light reflecting layer opposing a light absorption layer, reflecting the rays not absorbed by the dye of the light absorption layer by the light reflecting layer, and returning them to the light absorption layer. Accordingly, the efficiency of the dye-sensitized solar cell may be improved.

The following examples illustrate the present invention in more detail. However, it is understood that the present invention is not limited by these examples.

### Example 1

A porous titanium dioxide thick film having a thickness of about 18 μm was formed by coating the upper surface of a fluorine tin oxide (FTO) transparent conductor with a titanium oxide (TiO₂) dispersed solution in an area of about 0.2 cm² through a Doctor Blade process and performing a heat treatment at about 450° C. for about 30 minutes. Subsequently, specimens were kept at about 80° C. to adsorb an Ru based dye (N719 or C₅₈H₈₆N₈O₈RuS₂).

A light reflecting layer was formed by depositing titanium oxide (TiO₂) and silicon oxide (SiO₂) on another FTO transparent conductor to have the thickness of about 69 nm and about 106 nm, respectively, and this is repeated nine times. Subsequently, an indium tin oxide (ITO) layer was formed on the light reflecting layer to have a thickness of about 200 nm through a sputtering method, and then a Pt layer was deposited in a thickness of about 200 nm.

Two electrodes were laminated by interposing a thermoplastic polymer film having a thickness of about 60 μm between the two FTO transparent conductors and compressing them for about 9 seconds at about 100° C. Subsequently, a dye-sensitized solar cell was manufactured by implanting an oxidation-reduction electrolyte into the space between the transparent conductors and hermetically sealing fine pores with a cover glass and the thermoplastic polymer film. The oxidation-reduction electrolyte was prepared by dissolving 0.62 M 1,2-dimethyl-3-hexylimidazolium iodide, 0.5 M 2-aminopyrimidine (2-aminopyrimidine), 0.1 M Lil, and 0.05 M I₂ in an acetonitrile solvent.

### Example 2

A dye-sensitized solar cell was manufactured according to the same method as Example 1, except that titanium oxide (TiO₂) and silicon oxide (SiO₂) were repeatedly deposited to have a thickness of about 65 nm and about 100 nm, respectively, nine times as a light reflecting layer.

### Example 3

A dye-sensitized solar cell was manufactured according to the same method as Example 1, except that titanium oxide (TiO₂) and silicon oxide (SiO₂) were repeatedly deposited to have a thickness of about 61 nm and about 94 nm, respectively, nine times as a light reflecting layer.

### Example 4

A dye-sensitized solar cell was manufactured according to the same method as Example 1, except that titanium oxide (TiO₂) and silicon oxide (SiO₂) were repeatedly deposited to have a thickness of about 57 nm and about 88 nm, respectively, nine times as a light reflecting layer.

### Comparative Example 1

A dye-sensitized solar cell was manufactured according to the same method as Example 4, except that no light reflecting layer was included.

Evaluation—1

The wavelength range reflected by the light reflecting layer of each of the dye-sensitized solar cells manufactured according to Examples 1 to 4 was measured.

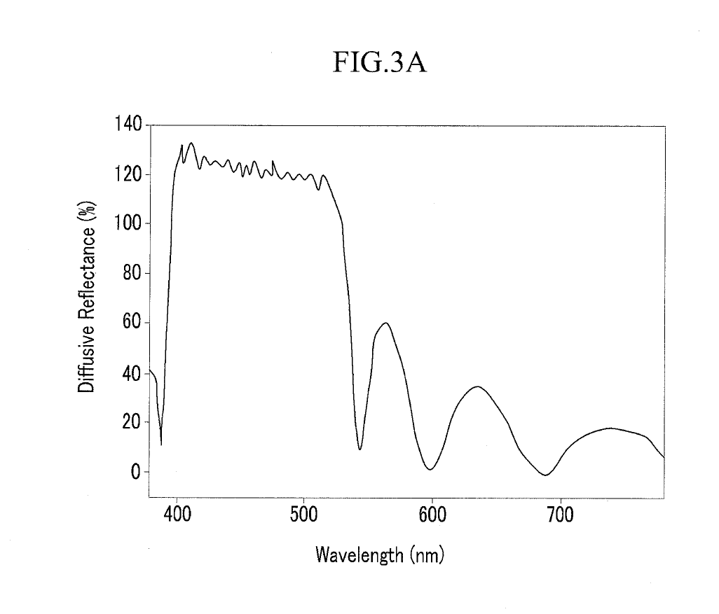

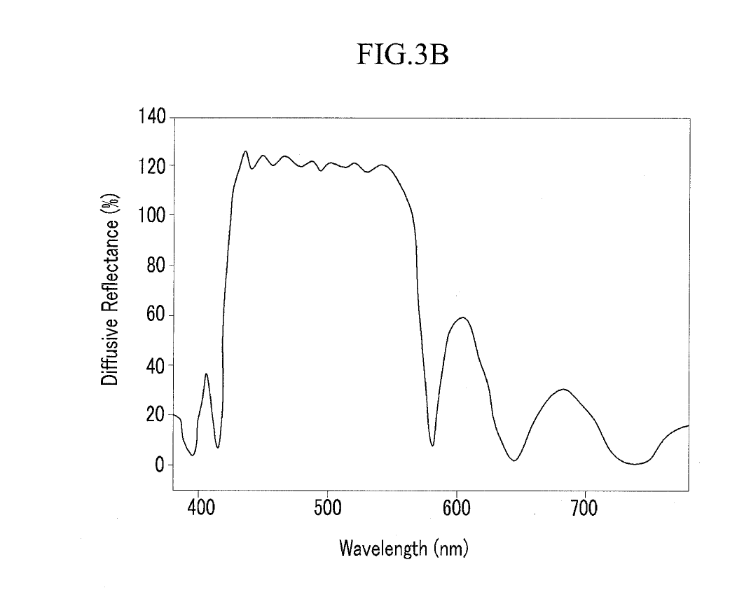

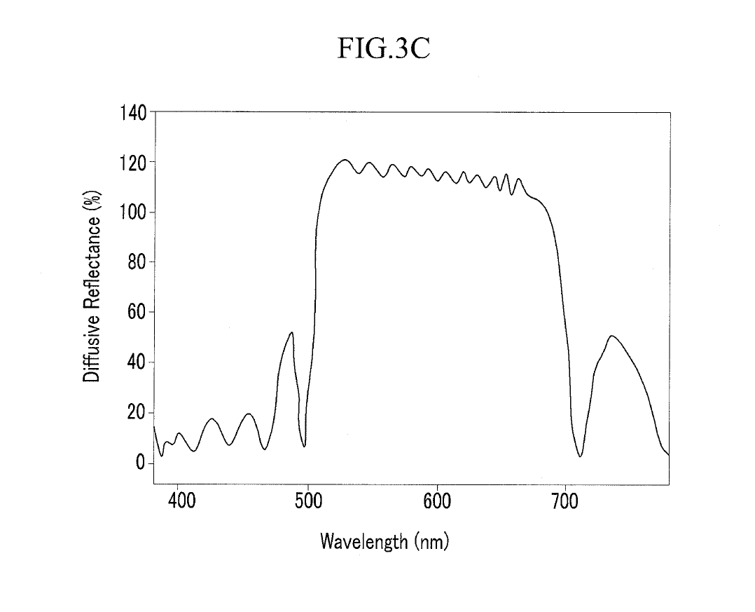

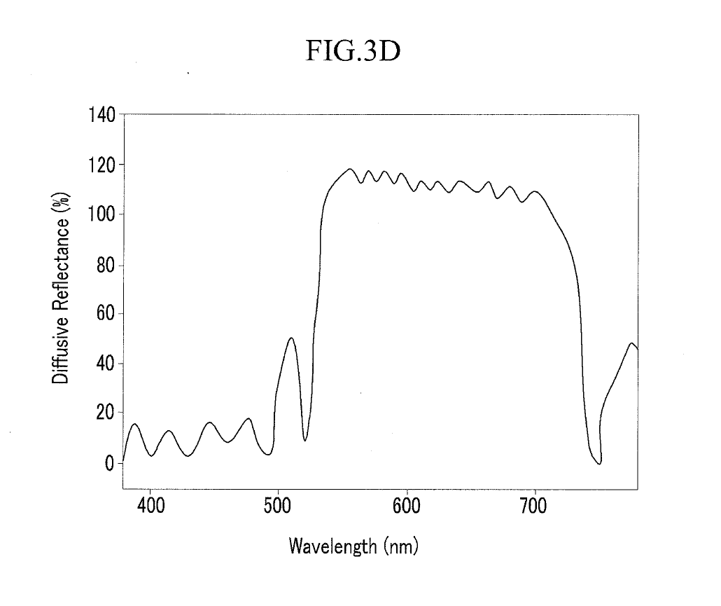

The result is described hereafter with reference to FIGS. 3A to 3D and Table 1.

FIGS. 3A to 3D are graphs showing the optical reflectances (diffusive reflectances) of dye-sensitized solar cells according to Examples 1 to 4.

TABLE 1

| | Reflecting wavelength range (nm) |
|---|---|
| Example 1 | 400-550 |
| Example 2 | 430-570 |
| Example 3 | 500-680 |
| Example 4 | 530-730 |

It may be seen from FIGS. 3A to 3D and Table 1 that the reflecting wavelength range may be changed by varying the thicknesses of the first oxide thin film and the second oxide thin film which have different refractive indices of light reflecting layer.

To be specific, FIG. 3A shows that the dye-sensitized solar cell of Example 1 had a reflectance of 100% or higher in the wavelength range of about 400 to about 550 nm; FIG. 3B shows that the dye-sensitized solar cell of Example 2 had a reflectance of 100% or higher in the wavelength range of about 430 to about 570 nm; FIG. 3C shows that the dye-sensitized solar cell of Example 3 had a reflectance of 100% or higher in the wavelength range of about 500 to about 680 nm; and FIG. 3D shows that the dye-sensitized solar cell of Example 4 had a reflectance of 100% or higher in the wavelength range of about 530 to about 730 nm.

It may be seen from the result that the reflectance may be controlled to be maximized in a particular wavelength by controlling the thicknesses of the first oxide thin film 11a and the second oxide thin film 11b which have different refractive indices and were stacked a plurality of times.

Evaluation—2

The current densities of the dye-sensitized solar cells manufactured according to Example 4 and Comparative Example 1 were measured.

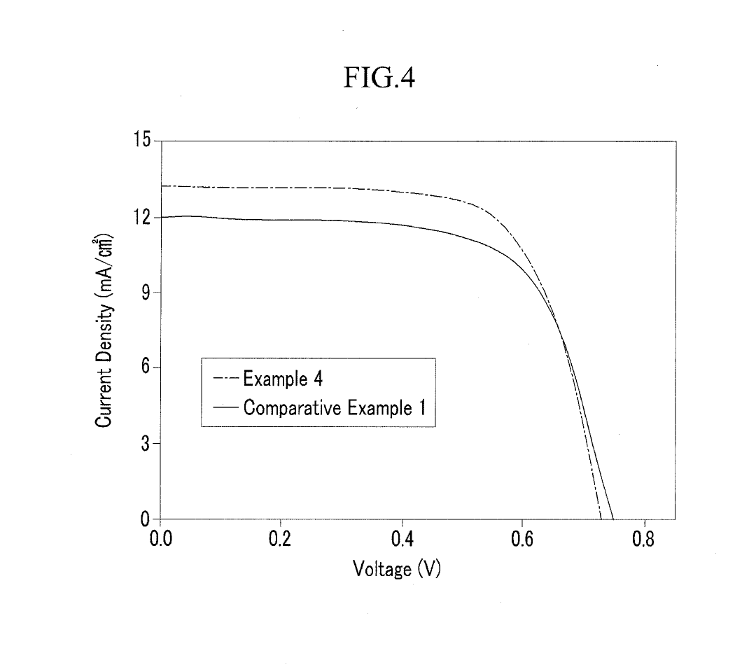

The result was as shown in FIG. 4.

FIG. 4 is a graph showing the current density of the dye-sensitized solar cells according to Example 4 and Comparative Example 1.

It may be seen from FIG. 4 that the dye-sensitized solar cell of Example 4 had higher current density than the dye-sensitized solar cell of Comparative Example 1.

Evaluation—3

The photocurrent efficiencies (Jsc) (mA/cm²), fill factors (FF) and percent efficiencies (%) of the dye-sensitized solar cells of Example 4 and Comparative Example 1 were measured.

The result was as shown in Table 2.

TABLE 2

| | Photocurrent efficiency | | |
|---|---|---|---|
| | (Jsc) (mA/cm²) | Fill factor (FF) | Efficiency (%) |
| Example 4 | 13.27 | 0.68 | 6.62 |
| Comparative | 12.11 | 0.67 | 6.01 |
| Example 1 | | | |

Table 2 shows that the dye-sensitized solar cell of Example 4 had improved photocurrent efficiency, fill factor and percent efficiency, compared with the dye-sensitized solar cell of Comparative Example 1. Since the dye-sensitized solar cell of Example 4 includes the light reflecting layer, the light reflected by the light reflecting layer is re-absorbed by the light absorption layer. Therefore, the optical amount is increased and the efficiency of a solar cell is improved.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A dye-sensitized solar cell comprising:
a first electrode,
a light absorption layer on one side of the first electrode,
a second electrode facing the first electrode,
a light reflecting layer on one side of the second electrode,
an electrolyte filled between the first electrode and the second electrode,
wherein the light reflecting layer comprises a plurality of thin films comprising a first oxide thin film and a second oxide thin film, the first oxide thin film having a different refractive index from the second oxide thin film, and the first and second oxide thin films being stacked alternately.

2. The dye-sensitized solar cell of claim 1, wherein:
the first oxide thin film comprises a titanium oxide (TiO₂), and
the second oxide thin film comprises a silicon oxide (SiO₂).

3. The dye-sensitized solar cell of claim 2, wherein each of the first oxide thin film and the second oxide thin film is formed to have a thickness at 10 nm or 800 nm or between 10 nm and 800 nm.

4. The dye-sensitized solar cell of claim 3, wherein the second oxide thin film is formed thicker than the first oxide thin film.

5. The dye-sensitized solar cell of claim 1, wherein the light reflecting layer reflects light of wavelength at 380 nm or 750 nm or between 380 nm and 750 nm.

6. The dye-sensitized solar cell of claim 5, wherein the light reflecting layer has a light reflecting wavelength varying in accordance to the thicknesses of the first oxide thin film and the second oxide thin film.

7. The dye-sensitized solar cell of claim 5, wherein the light reflecting layer has a reflectance higher than about 100%.

8. The dye-sensitized solar cell of claim 1, wherein the light absorption layer comprises titanium oxide (TiO₂) and a photosensitive dye adsorbed to TiO₂.

9. The dye-sensitized solar cell of claim 1, wherein the second electrode comprises Pt, Au, Ni, Cu, Ag, In, Ru, Pd, Rh, Ir, Os, C, a conductive polymer or a combination thereof.

10. The dye-sensitized solar cell of claim 1, wherein:
at least one of the first electrode or the second electrode is supported by a conductive transparent substrate, and
the conductive transparent substrate comprises indium tin oxide, fluorine tin oxide, ZnO—(Ga₂O₃ or Al₂O₃), tin oxide, zinc oxide, or a combination thereof.

11. The dye-sensitized solar cell of claim 1, wherein:
the first oxide thin film comprises a number (N) of first oxide films,
the second oxide thin film comprises a number (N) of second oxide thin films, and N is 2 or more.

12. The dye-sensitized solar cell of claim 11, wherein N is 9.
